(19) United States
(12) Patent Application Publication
(10) Pub. No.: US 2024/0389297 A1
(43) Pub. Date: Nov. 21, 2024

(54) SEMICONDUCTOR DEVICE INCLUDING MEMORY ELEMENT

(71) Applicant: Unisantis Electronics Singapore Pte. Ltd., Singapore (SG)

(72) Inventors: Nozomu HARADA, Tokyo (JP); Masakazu KAKUMU, Tokyo (JP); Koji SAKUI, Tokyo (JP)

(21) Appl. No.: 18/660,471

(22) Filed: May 10, 2024

(30) Foreign Application Priority Data
May 15, 2023 (WO) PCT/JP2023/018155

(51) Int. Cl. H10B 12/00

(52) U.S. Cl. CPC H10B 12/20

(57) ABSTRACT

A first impurity region that is connected to a first semiconductor layer, a first gate insulating layer that is in contact with the first semiconductor layer, a first gate conductor layer that is in contact with the first gate insulating layer, a second semiconductor layer that is in contact with a top of the first semiconductor layer, a second and third impurity regions that are along both edges of the second semiconductor layer in a horizontal direction, a second gate insulating layer that covers the second semiconductor layer between the second and third impurity regions, and a second gate conductor layer that is in contact with a top of the second gate insulating layer are included. Positions of both edges of the second semiconductor layer in a second direction perpendicular to a first direction are inside positions of both edges of the first semiconductor layer in a plan view.

### CROSS-REFERENCE TO RELATED APPLICATIONS

This application claims priority to PCT/JP2023/018155, filed May 15, 2023, the entire content of which is incorporated herein by reference.

### BACKGROUND OF THE INVENTION

### 1. Field of the Invention

The present invention relates to a semiconductor device including a memory element.

### 2. Description of the Related Art

In recent years, there has been a need for the high integrity, high performance, low power consumption, and high functionality of semiconductor devices that use memory elements in the technological development of large scale integration (LSI).

As for a typical planar MOS transistor, a channel extends in a horizontal direction parallel with an upper surface of a semiconductor substrate. However, a channel of a SGT extends in a direction perpendicular to an upper surface of a semiconductor substrate (see, for example, Japanese Unexamined Patent Application Publication No. 2-188966, and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp.573-578 (1991)). For this reason, the SGT enables a semiconductor device to have a density higher than that of the planar MOS transistor. The SGT is used as a selection transistor, and consequently, the high integrity can be achieved, for example, for a dynamic random access memory (DRAM, see, for example, H. Chung, H. Kim, H. Kim, K. Kim, S. Kim, K. W. Song, J. Kim, Y. C. Oh, Y. Hwang, H. Hong, G. Jin, and C. Chung: “4F2 DRAM Cell with Vertical Pillar Transistor (VPT),” 2011 Proceeding of the European Solid-State Device Research Conference, (2011)) to which a capacitor is connected, a phase change memory (PCM, see, for example, H. S. Philip Wong, S. Raoux, S. Kim, Jiale Liang, J. R. Reifenberg, B. Rajendran, M. Asheghi and K. E. Goodson: “Phase Change Memory,” Proceeding of IEEE, Vol. 98, No 12, December, pp2b012b27 (2010)) to which a resistive change element is connected, a resistive random access memory (RRAM, see, for example, K. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3V,” IEDM (2007)), and a magneto-resistive random access memory (MRAM, see, for example, W. Kang, L. Zhang, J. Klein, Y. Zhang, D. Ravelosona, and W. Zhao: “Reconfigurable Codesign of STT-MRAM Under Process Variations in Deeply Scaled Technology,” IEEE Transaction on Electron Devices, pp.1-9(2015)) that changes the direction of magnetic spin by using an electric current and that changes resistance. In addition, a memory cell (see M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron,” IEEE Electron Device Letter, Vol. 31, No. 5, pp.405-407 (2010)) includes a single MOS transistor that includes no capacitor, and a memory cell (see Md. Hasan Raza Ansari, Nupur Navlakha, Jae Yoon Lee, Seongjae Cho, “Double-Gate Junctionless 1T DRAM With Physical Barriers for Retention Improvement”, IEEE Trans, on Electron Devices vol. 67, pp.1471-1479 (2020)) has a groove in which a carrier is stored and two gate electrodes. However, there is a problem in that a DRAM that includes no capacitor is greatly affected by coupling of a gate electrode from a word line of a floating body, and a voltage margin is not sufficiently maintained. A memory element includes a MOS transistor that writes and reads data and a second channel that has a MOS structure connected below a first channel of the MOS transistor and that stores signal charges that correspond to “1”, “0” memory data (see, for example, US 2023/0077140 A1). The high integrity and high performance of the memory are needed. The present disclosure relates to a memory device using a semiconductor element that includes neither a resistive change element nor a capacitor and that can be achieved by using only a MOS transistor.

### SUMMARY OF THE INVENTION

There is a need for the high precision, high integrity, and reduced costs of a memory element that includes a MOS transistor that writes data and that reads data and a second channel that has a MOS structure connected below a first channel of the MOS transistor and that stores signal charges that correspond to “1”, “0” memory data.

To solve the problems described above, a semiconductor device including a memory element according to a first aspect includes a first semiconductor layer that is erected above a substrate in a direction perpendicular to the substrate and that is columnar, a first impurity region that is connected to a bottom portion of the first semiconductor layer, a first gate insulating layer that is in contact with a side surface of the first semiconductor layer, a first gate conductor layer that is in contact with the first gate insulating layer, a first insulating layer that insulates the first impurity region and the first gate conductor layer from each other, a second semiconductor layer that includes a bottom portion that is in contact with a top of the first semiconductor layer, a second insulating layer that is on the first gate conductor layer and that surrounds a vicinity of a boundary between the first semiconductor layer and the second semiconductor layer, a second gate insulating layer that is in contact with the second semiconductor layer, a second gate conductor layer that is in contact with the second gate insulating layer, and a second impurity region and a third impurity region that are along both edges of the second semiconductor layer in a first direction in a plan view. Positions of both edges of the top of the first semiconductor layer in a second direction perpendicular to the first direction are outside positions of both edges of the bottom portion of the second semiconductor layer in a plan view.

According to a second aspect, the first gate conductor layer is connected to a plate line, the second gate conductor layer is connected to a word line, the first impurity region is connected to a control line, the second impurity region is connected to a source line, and the third impurity region is connected to a bit line, as for the first aspect described above.

According to a third aspect, positions of both edges of the second gate conductor layer in the first direction and the second direction substantially match positions of both edges of the second semiconductor layer in a plan view, and a metal wiring layer is in contact with the second gate conductor layer and extends in the second direction, as for the first aspect described above.

According to a fourth aspect, the first gate conductor layer is divided into multiple gate conductor layers in a plan view, and the divided gate conductor layers are driven by applying a synchronous or asynchronous voltage thereto, as for the first aspect described above.

According to a fifth aspect, the first impurity region is isolated from an adjacent memory cell, and the third impurity region that has conductivity opposite that of the first impurity region is in contact with a bottom of the first impurity region, as for the first aspect described above.

According to a sixth aspect, the first impurity region extends in a direction in which the word line extends in a plan view, is shared with an adjacent memory cell that is located in the direction in which the word line extends, and is isolated from an adjacent memory cell that is located in a direction perpendicular to the direction in which the word line extends, as for the first aspect described above.

According to a seventh aspect, the first gate conductor layer is divided into multiple gate conductor layers in a plan view, and the divided gate conductor layers are synchronously or asynchronously driven, as for the first aspect described above.

According to an eighth aspect, a voltage that is applied to the first to third impurity regions and the first and second gate conductor layers is controlled, an electric current is caused to flow through the second semiconductor layer between the second impurity region and the third impurity region, and a data writing operation is performed such that a majority carrier in electrons and holes that are generated in the second semiconductor layer due to an impact ionization phenomenon or a gate-induced drain leakage (GIDL) current is mainly stored in the first semiconductor layer by using the electric current, and a data wiping operation is performed such that the majority carrier that is stored in the first semiconductor layer is discharged from the first semiconductor layer, as for the first aspect described above.

### BRIEF DESCRIPTION OF THE DRAWINGS

FIG. 1A, FIG. 1B, FIG. 1C, and FIG. 1D are diagrams for describing the operation of a semiconductor device that uses a memory element according to an embodiment.

FIG. 2AA, FIG. 2AB, and FIG. 2AC are diagram for describing a method of manufacturing a semiconductor device that includes a memory element according to a first embodiment.

FIG. 2BA, FIG. 2BB, and FIG. 2BC are diagrams for describing the method of manufacturing the semiconductor device that includes the memory element according to the first embodiment.

FIG. 2CA, FIG. 2CB, and FIG. 2CC are diagrams for describing the method of manufacturing the semiconductor device that includes the memory element according to the first embodiment.

FIG. 2DA, FIG. 2DB, and FIG. 2DC are diagrams for describing the method of manufacturing the semiconductor device that includes the memory element according to the first embodiment.

FIG. 2EA, FIG. 2EB, and FIG. 2EC are diagrams for describing the method of manufacturing the semiconductor device that includes the memory element according to the first embodiment.

FIG. 2FA, FIG. 2FB, and FIG. 2FC are diagrams for describing the method of manufacturing the semiconductor device that includes the memory element according to the first embodiment.

FIG. 2GA, FIG. 2GB, and FIG. 2GC are diagrams for describing the method of manufacturing the semiconductor device that includes the memory element according to the first embodiment.

FIG. 2HA, FIG. 2HB, and FIG. 2HC are diagrams for describing the method of manufacturing the semiconductor device that includes the memory element according to the first embodiment.

FIG. 2IA, FIG. 2IB, and FIG. 2IC are diagrams for describing the method of manufacturing the semiconductor device that includes the memory element according to the first embodiment.

FIG. 2JA, FIG. 2JB, and FIG. 2JC are diagrams for describing the method of manufacturing the semiconductor device that includes the memory element according to the first embodiment.

FIG. 2KA, FIG. 2KB, and FIG. 2KC are diagrams for describing the method of manufacturing the semiconductor device that includes the memory element according to the first embodiment.

FIG. 2LA, FIG. 2LB, and FIG. 2LC are diagrams for describing the method of manufacturing the semiconductor device that includes the memory element according to the first embodiment.

FIG. 2MA, FIG. 2MB, and FIG. 2MC are diagrams for describing the method of manufacturing the semiconductor device that includes the memory element according to the first embodiment.

FIG. 3AA, FIG. 3AB, and FIG. 3AC are diagrams for describing a method of manufacturing a semiconductor device that includes a memory element according to a second embodiment.

FIG. 3BA, FIG. 3BB, and FIG. 3BC are diagrams for describing the method of manufacturing the semiconductor device that includes the memory element according to the second embodiment.

FIG. 3CA, FIG. 3CB, and FIG. 3CC are diagrams for describing the method of manufacturing the semiconductor device that includes the memory element according to the second embodiment.

FIG. 3DA, FIG. 3DB, and FIG. 3DC are diagrams for describing the method of manufacturing the semiconductor device that includes the memory element according to the second embodiment.

FIG. 3EA, FIG. 3EB, and FIG. 3EC are diagrams for describing the method of manufacturing the semiconductor device that includes the memory element according to the second embodiment.

FIG. 4AA, FIG. 4AB, and FIG. 4AC are diagrams for describing a method of manufacturing a semiconductor device that includes a memory element according to a third embodiment.

FIG. 4BA, FIG. 4BB, and FIG. 4BC are diagrams for describing the method of manufacturing the semiconductor device that includes the memory element according to the third embodiment.

FIG. 5AA, FIG. 5AB, and FIG. 5AC are diagrams for describing a method of manufacturing a memory cell that includes a memory element according to a fourth embodiment.

FIG. 5BA, FIG. 5BB, and FIG. 5BC are diagrams for describing the method of manufacturing the memory cell that includes the memory element according to the fourth embodiment.

FIG. 5CA, FIG. 5CB, and FIG. 5CC are diagrams for describing the method of manufacturing the memory cell that includes the memory element according to the fourth embodiment.

FIG. 5DA, FIG. 5DB, and FIG. 5DC are diagrams for describing the method of manufacturing the memory cell that includes the memory element according to the fourth embodiment.

FIG. 5EA, FIG. 5EB, and FIG. 5EC are diagrams for describing the method of manufacturing the memory cell that includes the memory element according to the fourth embodiment.

FIG. 5FA, FIG. 5FB, and FIG. 5FC are diagrams for describing the method of manufacturing the memory cell that includes the memory element according to the fourth embodiment.

### DESCRIPTION OF THE PREFERRED EMBODIMENTS

A semiconductor device that uses a memory element and a method of manufacturing the semiconductor device according to an embodiment of the present invention will now be described with reference the drawings.

### First Embodiment

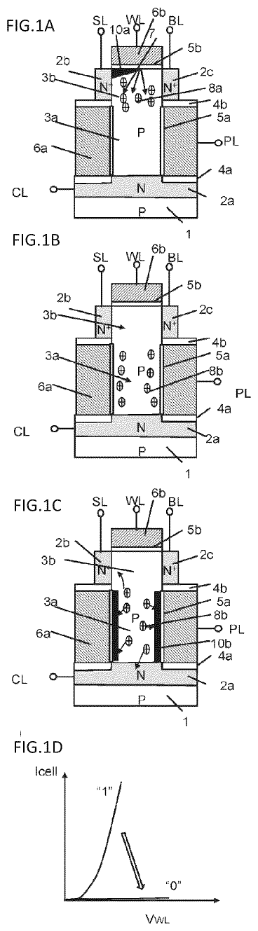

The operation of a memory cell according to a first embodiment will be described with reference to FIG. 1A, FIG. 1B, FIG. 1C, and FIG. 1D. Data writing and data holding operations of the memory cell will be described with reference to FIG. 1A and FIG. 1B. A mechanism of the memory cell for wiping data will be described with reference to FIG. 1C. A relationship of a memory cell current Icell with respect to a word line voltage V_{WL} as for data “1” and “0” will be described with reference to FIG. 1D. As for an actual memory device, multiple memory cells are arranged in a two-dimensional array on a substrate.

FIG. 1A, FIG. 1B, FIG. 1C, and FIG. 1D illustrate the structure of a vertical section of the memory cell. On a P-layer substrate 1 is an N-layer 2a that is a semiconductor region that contains donor impurities (a semiconductor region that contains donor impurities is referred to below as an “N-layer”). On the N-layer 2a is a first semiconductor layer 3a that contains acceptor impurities and that is columnar (a semiconductor region that contains acceptor impurities is referred to below as a “P-layer”). An insulating layer 4a covers an upper surface of the N-layer 2a along the outer periphery of the first semiconductor layer 3a that is columnar. A first gate insulating layer 5a is in contact with a side surface of the first semiconductor layer 3a. A first gate conductor layer 6a is in contact with a side surface of the first gate insulating layer 5a. On the first gate insulating layer 5a and the first gate conductor layer 6a is a second insulating layer 4b. On the first semiconductor layer 3a is a second semiconductor layer 3b. On an upper surface of the second semiconductor layer 3b is a second gate insulating layer 5b. A second gate conductor layer 6b is in contact with an upper surface of the second gate insulating layer 5b. Along an edge of the second semiconductor layer 3b is an N⁺-layer 2b that is a semiconductor region that contains donor impurities at a high concentration (a semiconductor region that contains donor impurities at a high concentration is referred to below as an “N⁺-layer”). Along another edge of the second semiconductor layer 3b opposite the N⁺-layer 2b is an N⁺-layer 2c.

The N⁺-layer 2b is connected to a source line SL. The N⁺-layer 2c is connected to a bit line BL. The first gate conductor layer 6a is connected to a plate line PL. The second gate conductor layer 6b is connected to a word line WL. The N-layer 2a is connected to a control line CL. The voltage of the source line SL, the bit line BL, the plate line PL, the word line WL, and the control line CL is operated, and consequently, the memory cell performs a memory operation.

A data writing operation of the memory cell according to the embodiment of the present invention will be described with reference to FIG. 1A. A MOS transistor that includes the N⁺-layer 2b that serves as a source, the N⁺-layer 2c that serves as a drain, the second gate insulating layer 5b that serves as a gate insulating layer, the second gate conductor layer 6b that serves as a gate, and the second semiconductor layer 3b that serves as a channel is formed in the memory cell. The MOS transistor is operated in a saturation region. Consequently, an inversion layer 10a that has a pinch-off point 7 is formed in the second semiconductor layer 3b right below the second gate insulating layer 5b.

As a result, as illustrated in FIG. 1A, an electric field is maximized in the vicinity of a boundary region between the pinch-off point 7 and the N⁺-layer 2c, and an impact ionization phenomenon occurs in this region. The impact ionization phenomenon causes electrons that are accelerated from the N⁺-layer 2b to the N⁺-layer 2c to collide with an Si lattice, and the kinetic energy thereof generates electron-hole pairs. Holes 8a that are generated diffuse due to the concentration gradient thereof toward a region in which the concentration of the holes reduces. Some of generated electrons flow into the second gate conductor layer 6b, but most of these flow into the N⁺-layer 2c that is connected to the bit line BL. The holes 8a may be generated by causing a gate-induced drain leakage (GIDL) current to flow instead of causing the impact ionization phenomenon described above to occur (see, for example, E. Yoshida, T, Tanaka, “A Capacitorless 1T-DARM Technology Using Gate-Induced Drain-Leakage (GIDL) Current for Low-Power and High-Speed Embedded Memory”, IEEE Trans, on Electron Devices vol. 53, pp.692-697 (2006)). The holes 8a may be generated due to the impact ionization phenomenon or the GIDL electric current by causing an electric current to flow between the N-layer 2a and the N⁺-layer 2b or 2c or between the N-layer 2a and the N⁺-layer 2b and between the N-layer 2a and the N⁺-layer 2c.

As illustrated in FIG. 1B, holes 8b that are some of the holes 8a are stored in the first semiconductor layer 3a after the data writing operation. That is, the holes 8b that correspond to signals are held in the first semiconductor layer 3a. The first semiconductor layer 3a and the second semiconductor layer 3b are electrically connected to each other, and accordingly, the first semiconductor layer 3a that substantially corresponds to a substrate of the MOS transistor that includes the second gate conductor layer 6b is charged at positive bias. The threshold voltage of the MOS transistor that includes the second gate conductor layer 6b reduces due to the positive substrate bias effect of the holes 8b that are mainly stored in the first semiconductor layer 3a that is columnar. Consequently, as illustrated in FIG. 1D, the threshold voltage of the MOS transistor that includes the second gate conductor layer 6b to which the word line WL is connected reduces. This writing state is assigned to logical memory data “1”. In a state in which the impact ionization phenomenon does not occur, and the holes 8b are not in the first semiconductor layer 3a, the threshold voltage of the MOS transistor that includes the second gate conductor layer 6b increases, and no electric current flows between the N⁺-layers 2b and 2c. As illustrated in FIG. 1D, this state is assigned to logical memory data “0”.

A data wiping operation will now be described with reference to FIG. 1C. The holes 8b are mainly stored in the first semiconductor layer 3a that is columnar before the data wiping operation. A voltage of, for example, 2 V is applied to the plate line PL, and an inversion layer 10b is formed in a surface layer of the first semiconductor layer 3a. A voltage of, for example, −0.5 V is applied to the control line CL, and a PN junction between the N-layer 2a and the first semiconductor layer 3a is at forward bias. Consequently, the holes 8b are recombined with the electrons in the inversion layer 10b and the N-layer 2a over time and are discharged. Consequently, as illustrated in FIG. 1D, the threshold voltage of the MOS transistor is higher than that when “1” is written and returns to the initial state, and the logical memory data “0” is obtained. Voltage conditions of the data wiping operation described above are examples for the data wiping operation and may be other voltage conditions in which the data wiping operation can be performed.

In FIG. 1A, FIG. 1B, FIG. 1C, and FIG. 1D, the N-layer 2a that is connected to the control line CL may be connected to an N-layer of an adjacent memory cell. The N-layer 2a may be formed only at a bottom portion of the first semiconductor layer 3a. In this case, the voltage of the N-layer 2a is applied by using the voltage that is applied to the P-layer substrate 1.

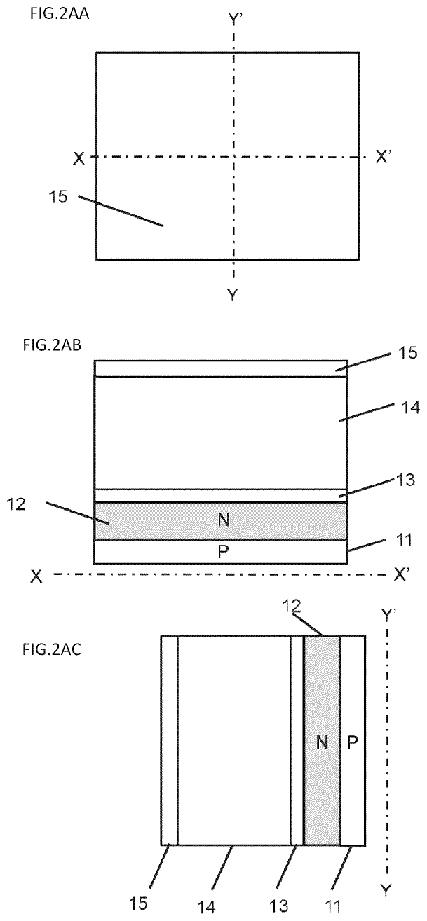

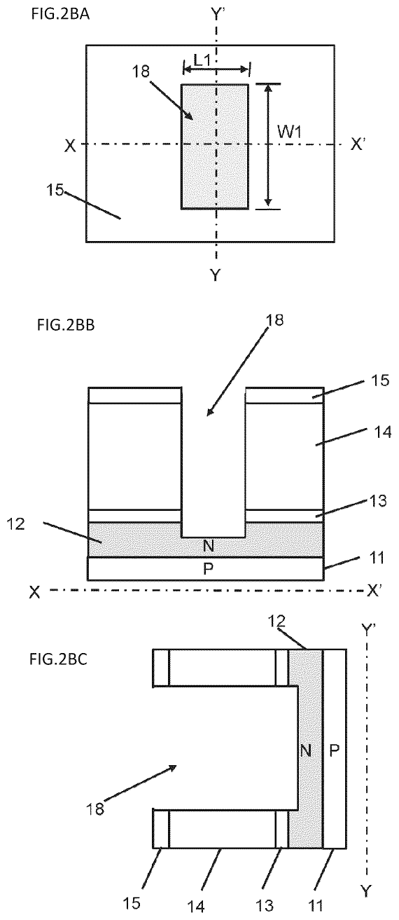

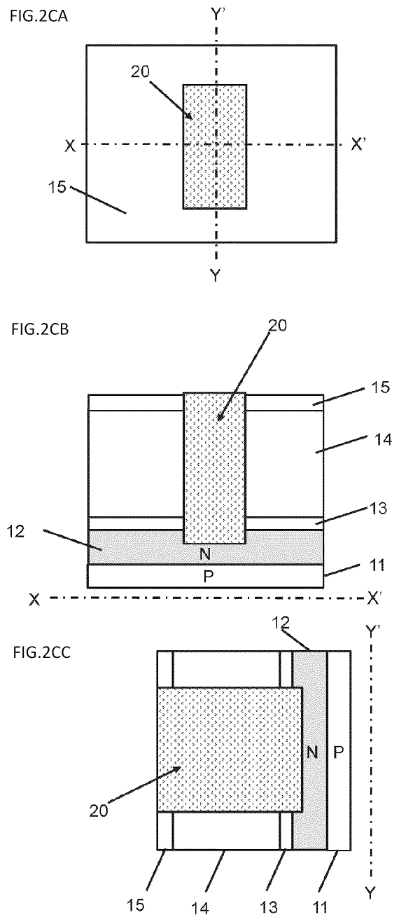

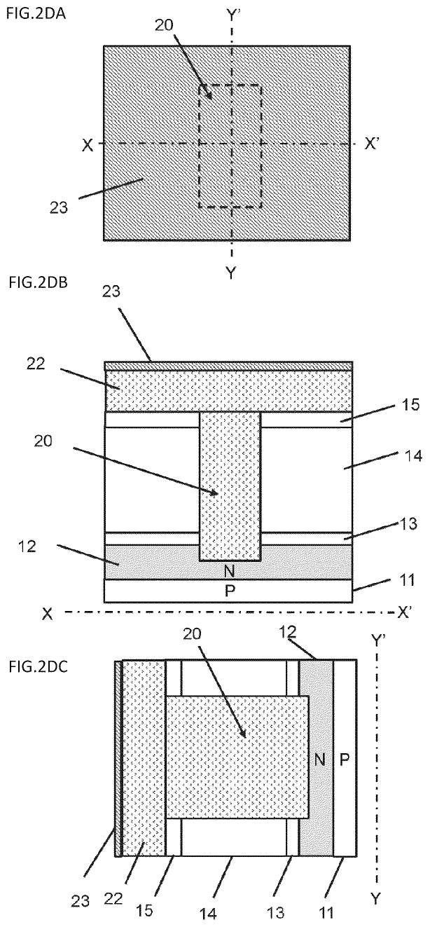

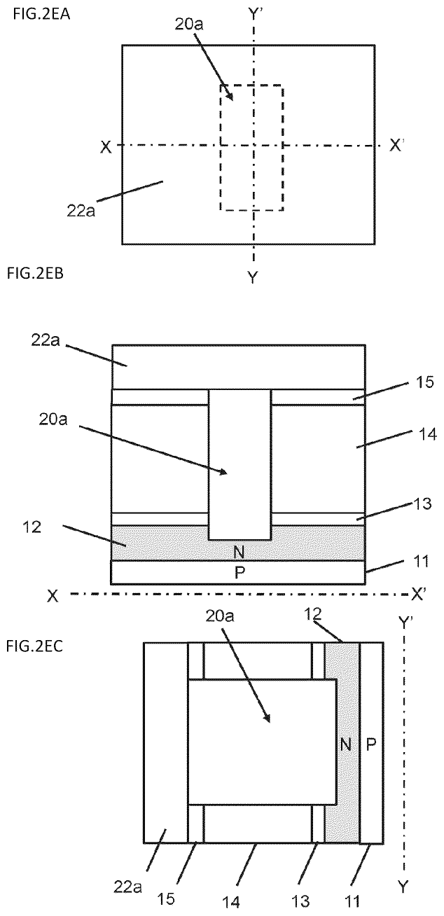

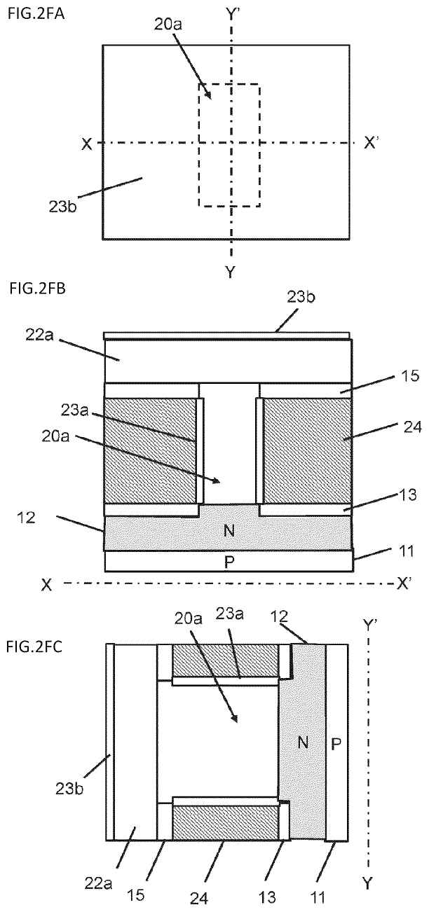

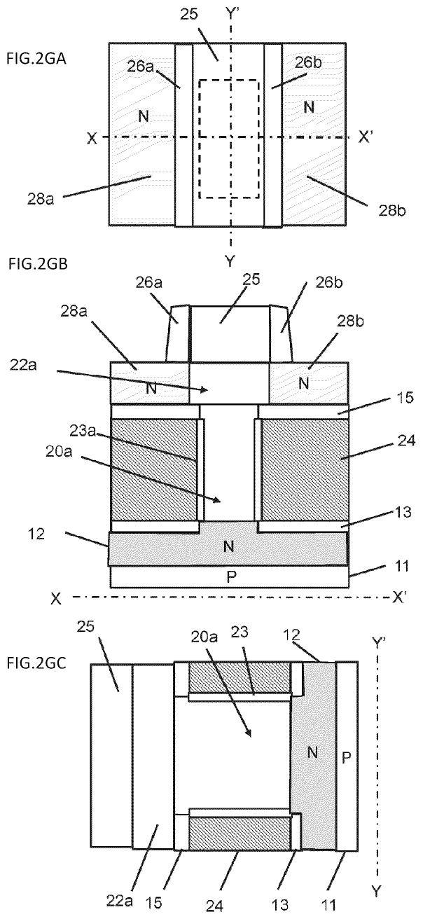

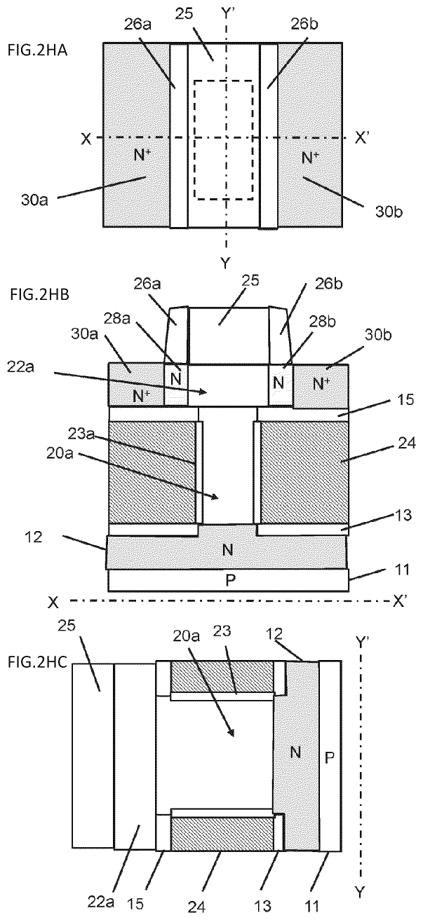

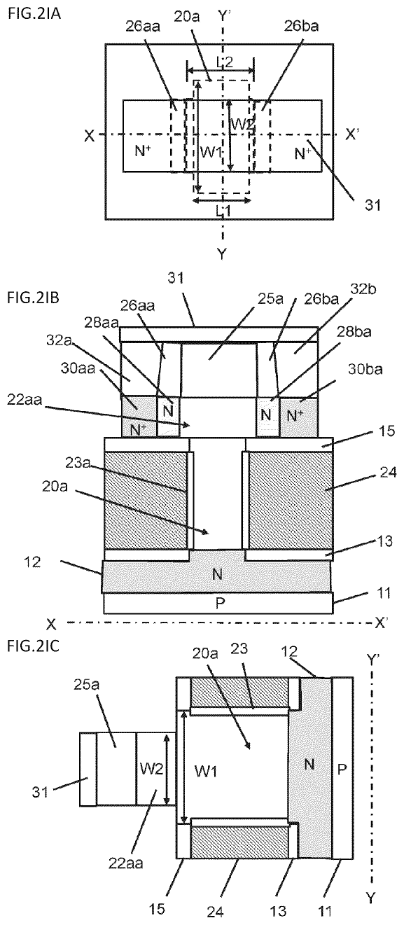

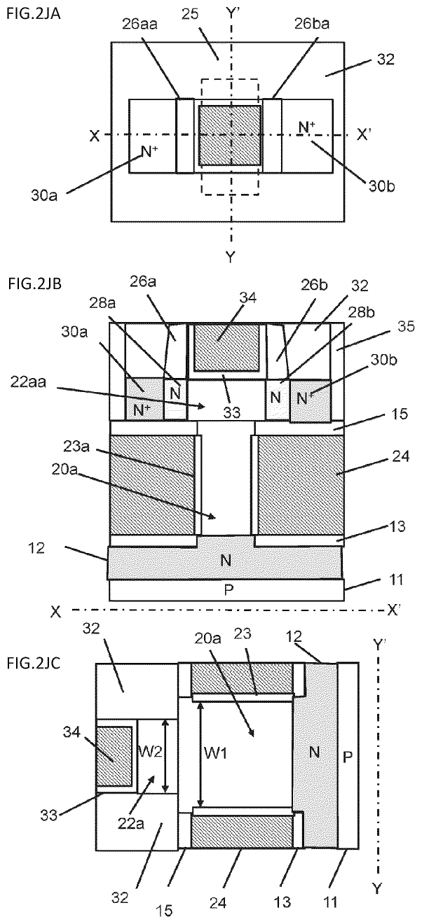

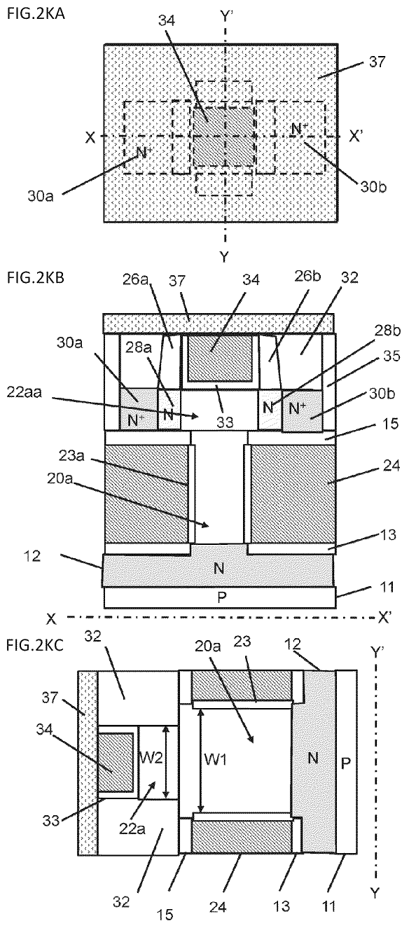

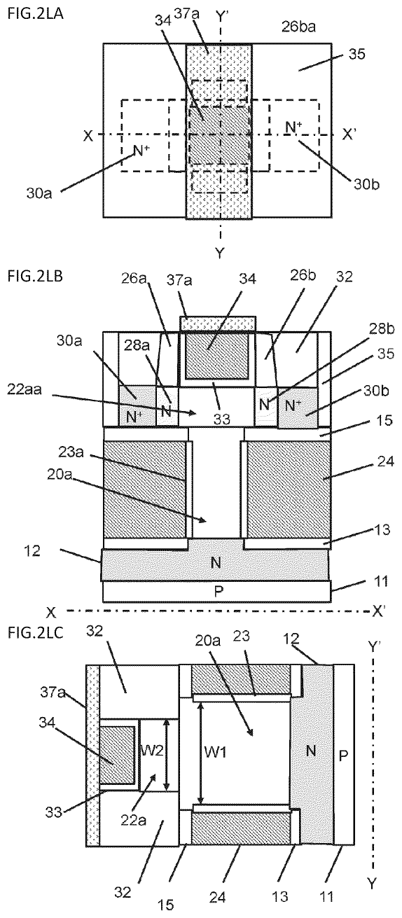

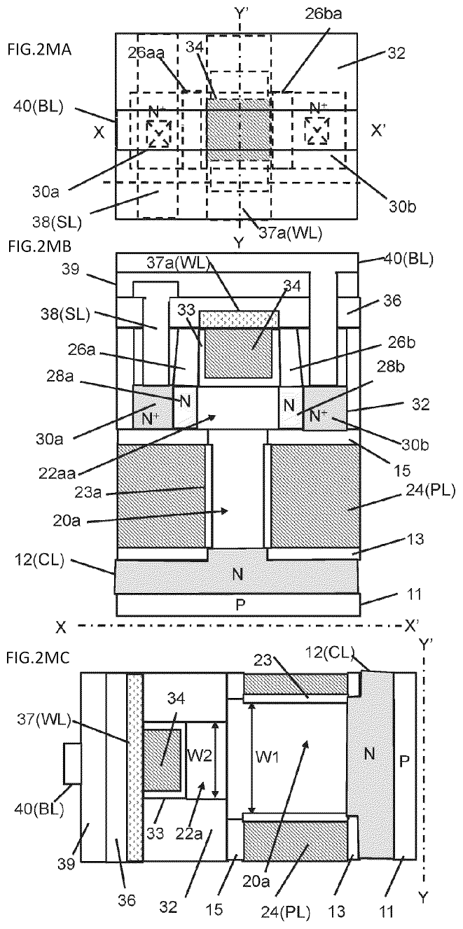

A method of manufacturing the memory cell according to the first embodiment will be described with reference to FIG. 2AA to FIG. 2KC. FIG. 2AA, FIG. 2BA, FIG. 2CA, FIG. 2DA, FIG. 2EA, FIG. 2FA, FIG. 2GA, FIG. 2HA, FIG. 2IA, FIG. 2JA, FIG. 2KA, FIG. 2LA, and FIG. 2MA illustrate the memory cell in a plan view. FIG. 2AB, FIG. 2BB, FIG. 2CB, FIG. 2DB, FIG. 2EB, FIG. 2FB, FIG. 2GB, FIG. 2HB, FIG. 2IB, FIG. 2JB, FIG. 2KB, FIG. 2LB, and FIG. 2MB illustrate a vertical section along a line X-X′ in the plan view in FIG. 2AA, FIG. 2BA, FIG. 2CA, FIG. 2DA, FIG. 2EA, FIG. 2FA, FIG. 2GA, FIG. 2HA, FIG. 2IA, FIG. 2JA, FIG. 2KA, FIG. 2LA, and FIG. 2MA. FIG. 2AC, FIG. 2BC, FIG. 2CC, FIG. 2DC, FIG. 2EC, FIG. 2FC, FIG. 2GC, FIG. 2HC, FIG. 2IC, FIG. 2JC, FIG. 2KC, FIG. 2LC, and FIG. 2MC illustrate a vertical section along a line Y-Y′ in the plan view in FIG. 2AA, FIG. 2BA, FIG. 2CA, FIG. 2DA, FIG. 2EA, FIG. 2FA, FIG. 2GA, FIG. 2HA, FIG. 2IA, FIG. 2JA, FIG. 2KA, FIG. 2LA, and FIG. 2MA. As for the actual memory device, multiple memory cells are arranged in a two-dimensional array on a substrate as described above.

As illustrated in FIG. 2AA, FIG. 2AB, and FIG. 2AC, an N-layer 12 is formed on a P-layer substrate 11 by, for example, ion implantation or epitaxial crystal growth. An SiO₂ layer 13, a silicon nitride (Si₃N₄) layer 14, and an SiO₂ layer 15 are formed above the N-layer 12 in this order.

Subsequently, as illustrated in FIG. 2BA, FIG. 2BB, and FIG. 2BC, a hole 18 that extends through the SiO₂ layer 15, the Si₃N₄ layer 14, and the SiO₂ layer 13 and that has a bottom portion in the N-layer 12 is formed by using a lithography method and a reactive ion etching (RIE) method. As illustrated in FIG. 2BA, the length of the hole 18 in the direction of the line X-X′ is designated as L1, and the length in the direction of the line Y-Y′ is designated as W1. In the case where each of sectional shapes of the hole 18 in both directions or a sectional shape thereof in one of the directions is a trapezoidal shape, W1 and L1 represent the dimensions of a top.

Subsequently, as illustrated in FIG. 2CA, FIG. 2CB, and FIG. 2CC, polycrystalline Si that fills an inner portion of the hole 18 and that covers an upper surface of the SiO₂ layer 15 is accumulated. A polycrystalline Si layer 20 an upper surface of which is polished so as to be flush with the upper surface of the SiO₂ layer 15 is formed by chemical mechanical polishing (CMP).

Subsequently, as illustrated in FIG. 2DA, FIG. 2DB, and FIG. 2DC, a polycrystalline Si layer 22 and an Ni layer 23 are formed above the polycrystalline Si layer 20 and the SiO₂ layer 15 in this order.

Subsequently, as illustrated in FIG. 2EA, FIG. 2EB, and FIG. 2EC, a heat treatment is performed, and an Si layer 22a that is a single crystal into which the polycrystalline Si layer 22 is converted and a first Si layer 20a that is a single crystal into which the polycrystalline Si layer 20 is converted and that is columnar are formed by using a metal-assisted Solid-Phase Crystallization (MILC) method (see, for example, H. Miyagawa et al. “Metal-Assisted Solid-Phase Crystallization Process for Vertical Monocrystalline Si Channel in 3D Flash Memory”, IEDM19 digest paper, pp. 650-653 (2019)).

Subsequently, the Si layer 22a, the SiO₂ layer 15, and the Si₃N₄ layer 14 along an outer periphery in a memory cell region are removed by RIE etching (not illustrated). As illustrated in FIG. 2FA, FIG. 2FB, and FIG. 2FC, an SiO₂ layer 23a is formed on a side surface of the first Si layer 20a, and an SiO₂ layer 23b is formed on an upper surface of the Si layer 22a by using a thermal oxidation method after the Si₃N₄ layer 14 is removed from the outer periphery in the memory cell region. A titanium nitride (TiN) layer 24 is formed such that a side surface of the SiO₂ layer 23a is covered, and a space in which the Si₃N₄ layer 14 is removed is filled. A layer composed of another material such as a hafnium oxide (HfO₂) layer that serves as a gate insulating layer by using, for example, an atomic layer deposition (ALD) method may be used instead of the SiO₂ layer 23a that is formed by thermal oxidation. A conductor layer that is to be another gate conductor layer such as doped polycrystalline Si in a single layer or a multilayer may be used instead of the TiN-layer 24.

Subsequently, the SiO₂ layer 23b is removed. As illustrated in FIG. 2GA, FIG. 2GB, and FIG. 2GC, a Si₃N₄ layer 25 that extends in the direction of the line Y-Y′ is formed on the Si layer 22a. Both edges of the Si₃N₄ layer 25 in the direction of the line X-X′ substantially overlap both edges of the first Si layer 20a. N-layers 28a and 28b that are to be a lightly doped drain (LDD) are formed by using an ion implantation method. SiO₂ layers 26a and 26b are formed along both sides of the Si₃N₄ layer 25 by using a chemical vaper deposition (CVD) method and the RIE etching.

Subsequently, as illustrated in FIG. 2HA, FIG. 2HB, and FIG. 2HC, arsenic (As), for example, is implanted into the N-layers 28a and 28b outside the Si₃N₄ layer 25 and the SiO₂ layers 26a and 26b in a plan view by using the ion implantation method, and N⁺ layers 30a and 30b are formed.

Subsequently, an SiO₂ layer (not illustrated) is formed outside the Si₃N₄ layer 25 and the SiO₂ layers 26a and 26b by using the CVD method and the CMP method. As illustrated in FIG. 2IA, FIG. 2IB, and FIG. 2IC, a second Si layer 22aa, N⁺ layers 30aa and 30ba, N-layers 28aa and 28ba, an Si₃N₄ layer 25a, and SiO₂ layers 26aa, 26ba, 32a, and 32b are formed with a mask material layer 31 used as an etching mask by using the lithography method and the RIE etching. The length W2 of the mask material layer 31 in the direction of the line Y-Y′ is shorter than the length W1 of the first Si layer 20a in the direction of the line Y-Y′, and both edges of the mask material layer 31 in the direction of the line Y-Y′ are inside both edges of the first Si layer 20a in a plan view. Consequently, the length W2 of a bottom portion of the second Si layer 22aa in the direction of the line Y-Y′ is shorter than the length W1 of the top of the first Si layer 20a in the direction of the line Y-Y′, and both edges of the second Si layer 22aa in the direction of the line Y-Y′ are inside both edges of the first Si layer 20a in a plan view. The mask material layer 31 is removed. The positions of both edges of the length L2 of the second Si layer 22aa in the direction of the line X-X′ may be inside or outside the positions of both edges of the length L1 of a first Si pillar in a plan view.

Subsequently, an SiO₂ layer (not illustrated) is accumulated by using the CVD method, and an upper surface is polished by using the CMP method up to the position of an upper surface of the Si₃N₄ layer 25a, and an SiO₂ layer 35 is formed. As illustrated in FIG. 2JA, FIG. 2JB, and FIG. 2JC, the Si₃N₄ layer 25a is removed by etching. A hafnium oxide (HfO₂) layer 33, for example, is formed on an inner surface after removal. A titanium nitride (TiN) layer 34, for example, is formed inside the HfO₂ layer 33. The HfO₂ layer 33 may be a single layer or a multilayer or may be another layer composed of a gate insulating material.

Subsequently, as illustrated in FIG. 2KA, FIG. 2KB, and FIG. 2KC, a metal layer 37 is formed on the entire upper surface.

Subsequently, as illustrated in FIG. 2LA, FIG. 2LB, and FIG. 2LC, the metal layer 37 is etched by using the lithography method and the RIE method, and a metal wiring layer 37a that is connected to the TiN-layer 34 that extends in the direction of the line Y-Y′ in a plan view is formed.

Subsequently, as illustrated in FIG. 2MA, FIG. 2MB, and FIG. 2MC, an SiO₂ layer 36 is entirely formed. A metal wiring layer 38 that is connected above the SiO₂ layer 36 via a contact hole on the N⁺ layer 30a and that extends in the direction of the line Y-Y′ in a plan view is formed. An SiO₂ layer 39 is entirely formed. A metal wiring layer 40 that is connected above the SiO₂ layer 39 via a contact hole on the N⁺ layer 30b and that extends in the direction of the line X-X′ in a plan view is formed.

As illustrated in FIG. 2MA, FIG. 2MB, and FIG. 2MC, the N-layer 12 is connected to the control line CL, the first gate conductor layer 24 is connected to the control line PL, the metal wiring layer 37a is connected to the word line WL, the metal wiring layer 38 is connected to the source line SL, and the metal wiring layer 40 is connected to the bit line BL.

In FIG. 2CA to FIG. 2EC, the first Si layer 20a and the Si layer 22a are formed by using the MILC method. However, the first Si layer 20a and the Si layer 22a may be formed by using another method such as a selective epitaxial crystal growth method.

The N-layers 28a and 28b that correspond to the LDD in contact with both edges of the second Si layer 22aa may not be provided. A portion or the whole of the region of the N-layers 28a and 28b may be a thermal diffusion region for the donor impurities from the N⁺ layers 30a and 30b.

The present embodiment has the following features.

(1) The memory cell is formed by using the first Si layer 20a that is erected above the P-layer substrate 11 in the perpendicular direction, the N-layer 12 that is connected to the bottom portion of the first Si layer 20a, the SiO₂ layer 23a that is a gate insulating layer that is in contact with a side surface of the Si pillar, the TiN-layer 24 that is a gate conductor layer that is in contact with the SiO₂ layer 23a, the SiO₂ layer 23a that insulates the N-layer 12 and the TiN-layer 24 from each other, the second Si layer 22aa that is in contact with the top of the first Si layer 20a, the SiO₂ layer 15 that is on the TiN-layer 24 and that surrounds the vicinity of the boundary between the first Si layer 20a and the Si layer 22a, the HfO₂ layer 33 that is a gate insulating layer that is in contact with the upper surface of the Si layer 22a, the TiN-layer 34 that is a gate conductor layer that is in contact with the HfO₂ layer 33, and the N⁺ layers 30a and 30b that are connected to both edges of the second Si layer 22aa in the horizontal direction, illustrated in FIG. 2KA, FIG. 2KB, and FIG. 2KC. As illustrated in FIG. 2KC, the length W2 of the second Si layer 22aa in the direction of the line Y-Y′ is shorter than the length W1 of the first Si layer 20a in the direction of the line Y-Y′, and both edges of the second Si layer 22aa are inside both edges of the first Si layer 20a in the direction of the line Y-Y′ in a plan view. Consequently, the entire length of a lower portion of the second Si layer 22aa in the direction of the line Y-Y′ is in contact with the top of the first Si layer 20a. As for the memory cell, the electric potential of the second Si layer 22aa that serves as the channel of the MOS transistor that includes the N⁺ layers 30a and 30b and the TiN-layer 34 of the gate is controlled due to the holes (the holes 8b in FIG. 1A, FIG. 1B, FIG. 1C, and FIG. 1D) that correspond to the signal charges that are stored in the first Si layer 20a with certainty. As a result, the memory cell that has a large difference between “1” and “0” signals is obtained.

(2) In addition, the length W1 of the first Si layer 20a in the direction of the line Y-Y′ is adjusted, and the number of the holes 8b that are stored in the first Si layer 20a that is needed for memory holding characteristics illustrated in FIG. 1B can be changed. As the length W1 increases, the number of the holes 8b can increase. The increase in the length W1 poses a problem in that a cell area increases but brings an advantage in obtaining the holding characteristics depending on the application specification of the memory device.

### Second Embodiment

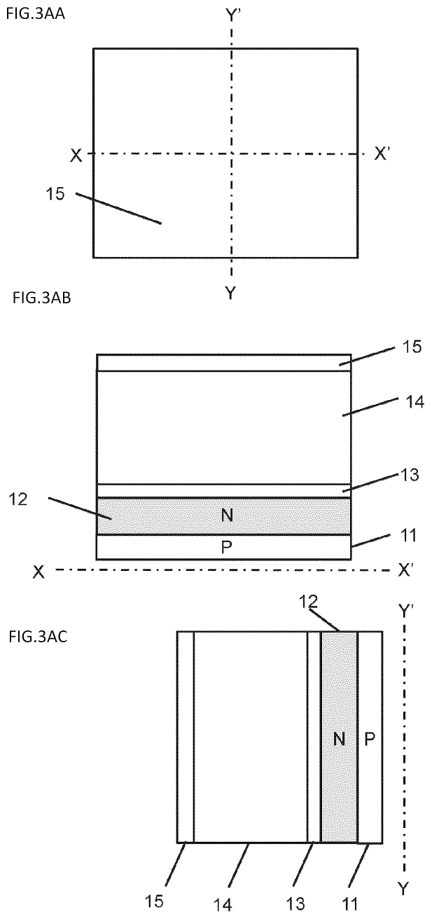

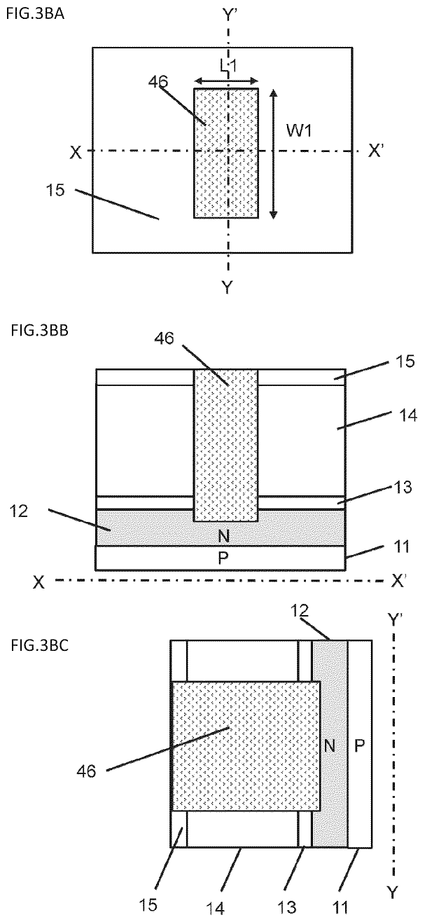

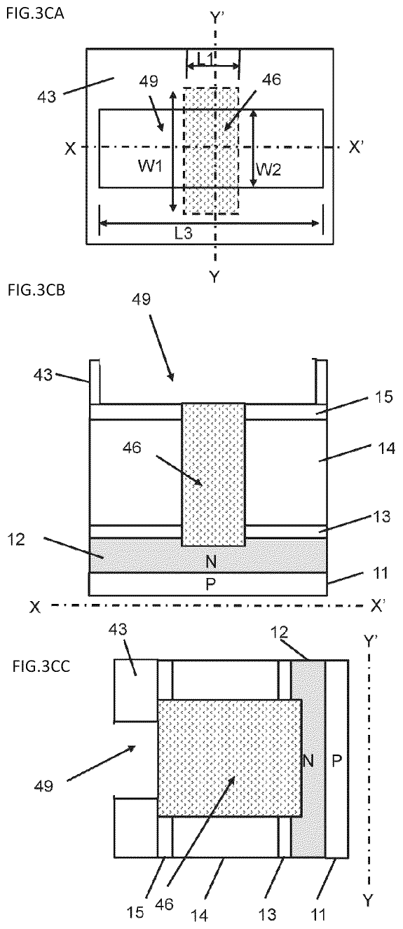

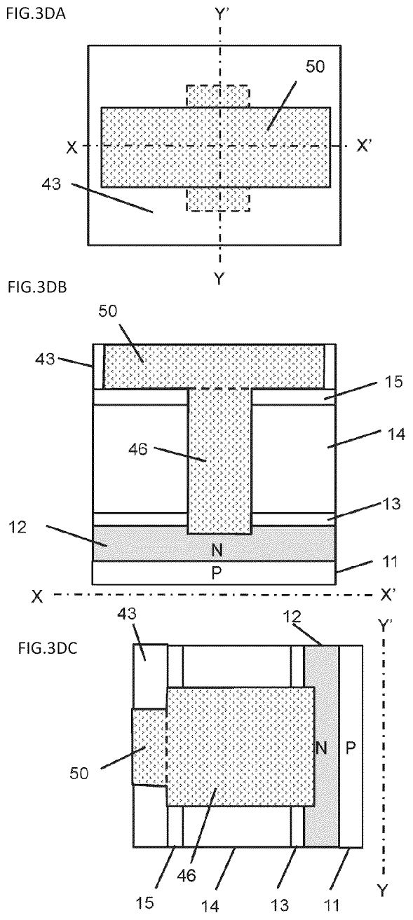

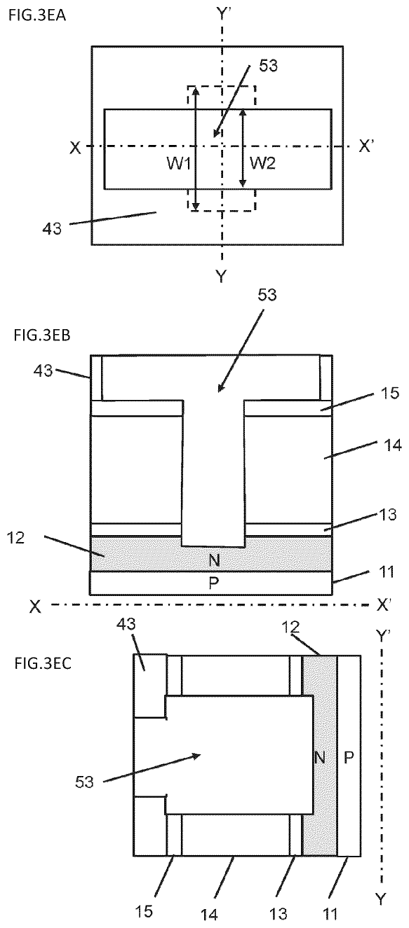

A method of manufacturing a memory cell according to a second embodiment will be described with reference to FIG. 3AA to FIG. 3EC. FIG. 3AA, FIG. 3BA, FIG. 3CA, FIG. 3DA, and FIG. 3EA illustrate the memory cell in a plan view. FIG. 3AB, FIG. 3BB, FIG. 3CB, FIG. 3DB, and FIG. 3EB illustrate a vertical section along a line X-X′ in FIG. 3AA, FIG. 3BA, FIG. 3CA, FIG. 3DA, and FIG. 3EA. FIG. 3AC, FIG. 3BC, FIG. 3CC, FIG. 3DC, and FIG. 3EC illustrate a vertical section along a line Y-Y′ in FIG. 3AA, FIG. 3BA, FIG. 3CA, FIG. 3DA, and FIG. 3EA. As for the actual memory device, multiple memory cells are arranged in a two-dimensional array on a substrate. A mechanism for driving the memory cell is the same as that illustrated in FIG. 1A, FIG. 1B, FIG. 1C, and FIG. 1D.

As illustrated in FIG. 3AA, FIG. 3AB, and FIG. 3AC, the N-layer 12, the SiO₂ layer 13, the Si₃N₄ layer 14, and the SiO₂ layer 15 are formed above the P-layer substrate 11 in this order as in FIG. 2AA, FIG. 2AB, and FIG. 2AC.

Subsequently, as illustrated in FIG. 3BA, FIG. 3BB, and FIG. 3BC, a hole (not illustrated) a bottom portion of which is adjacent to the N-layer is formed by using the lithography method and the RIE etching method, the hole is subsequently filled, and a polycrystalline Si layer 46, for example, is formed. The length of the polycrystalline Si layer 46 in the direction of the line X-X′ is designated as L1, and the length in the direction of the line Y-Y′ is designated as W1 in a plan view. W1 and L1 represent the dimensions of the top of the polycrystalline Si layer 46 in a plan view as in the case of FIG. 2AA to FIG. 2MC.

Subsequently, as illustrated in FIG. 3CA, FIG. 3CB, and FIG. 3CC, an Si₃N₄ layer 43 is entirely formed, and subsequently, the Si₃N₄ layer 43 is etched by using the lithography method and RIE. A hole 49 having the length L3 in the direction of the line X-X′ and the length W2 in the direction of the line Y-Y′ is formed on the SiO₂ layer 15 and the polycrystalline Si layer 46 in a plan view. The positions of both edges of a bottom portion of the hole 49 are outside the positions of both edges of an upper surface of the polycrystalline Si layer 46 in the direction of the line Y-Y′ in a plan view.

Subsequently, as illustrated in FIG. 3DA, FIG. 3DB, and FIG. 3DC, the hole 49 is filled, and a polycrystalline Si layer 50 is formed.

Subsequently, as illustrated in FIG. 3EA, FIG. 3EB, and FIG. 3EC, an Ni layer, for example, is formed on the polycrystalline Si layer 50, the polycrystalline Si layers 46 and 50 are converted into single crystals by using the MILC method, and an Si layer 53 is formed as in FIG. 2AA to FIG. 2MC. Subsequently, the same processing as that in FIG. 2FA to FIG. 2KC is performed, and the memory cell is formed on the P-layer substrate 11.

In FIG. 2DA, FIG. 2DB, and FIG. 2DC, the polycrystalline Si layer 22 is formed over the entire surface of the polycrystalline Si layer 20 and the SiO₂ layer 15. According to the present embodiment, however, the hole 49 that is surrounded by the Si₃N₄ layer 43 is formed, and subsequently, the polycrystalline Si layer 50 is formed in the hole 49 on the SiO₂ layer 15 and the polycrystalline Si layer 46. The polycrystalline Si layers 46 and 50 are converted into single crystals by using the MILC method, and the Si layer 53 is formed. In this way, the Si layer 53 that corresponds to the first semiconductor layer 3a and the second semiconductor layer 3b in FIG. 1A, FIG. 1B, FIG. 1C, and FIG. 1D can be formed.

### Third Embodiment

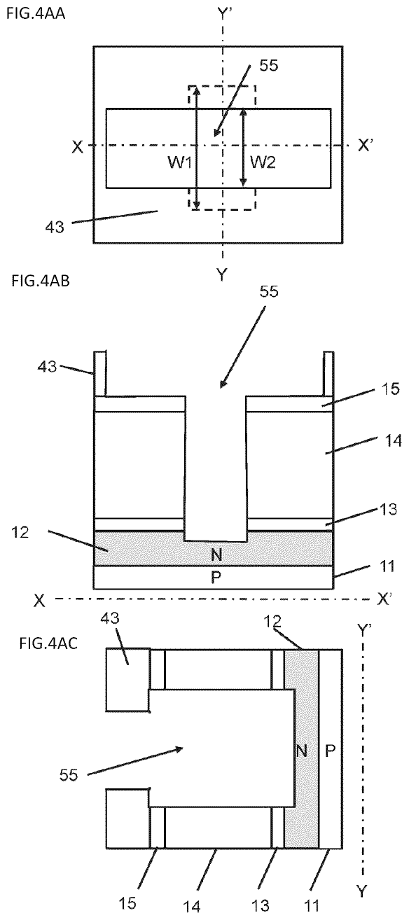

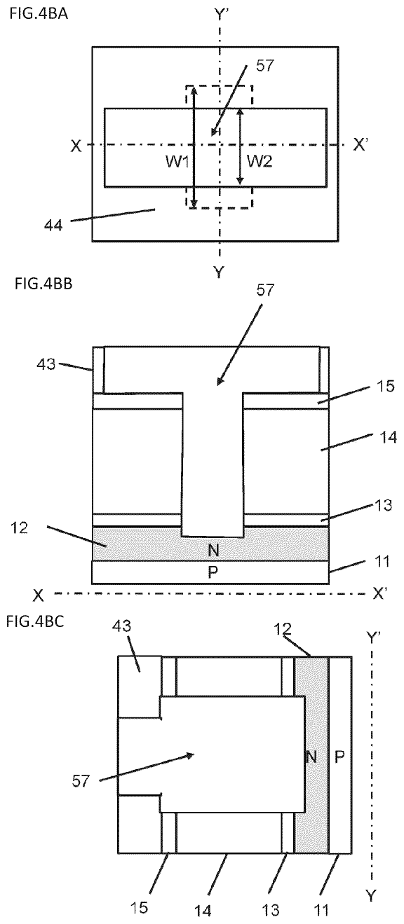

A method of manufacturing a memory cell according to a third embodiment will be described with reference to FIG. 4AA, FIG. 4AB, FIG. 4AC, FIG. 4BA, FIG. 4BB, and FIG. 4BC. FIG. 4AA and FIG. 4BA illustrate the memory cell in a plan view. FIG. 4AB and FIG. 4BB illustrate a vertical section along a line X-X′ in FIG. 4AA and FIG. 4BA. FIG. 4AC and FIG. 4BC illustrate a vertical section along a line Y-Y′ in FIG. 4AA and FIG. 4BA. As for the actual memory device, multiple memory cells are arranged in a two-dimensional array on a substrate. A mechanism for driving the memory cell is the same as that illustrated in FIG. 1A, FIG. 1B, FIG. 1C, and FIG. 1D.

In processing illustrated in FIG. 3CA, FIG. 3CB, and FIG. 3CC, the polycrystalline Si layer 46 is removed, and a hole 55 illustrated in FIG. 4AA, FIG. 4AB, and FIG. 4AC is formed.

Subsequently, a Si layer (not illustrated) in which the hole 55 is filled such that an upper surface is located above an upper surface of the Si₃N₄ layer 43 is formed by the selective epitaxial crystal growth method. Subsequently, as illustrated in FIG. 4BA, FIG. 4BB, and FIG. 4BC, an Si layer 57 is formed such that an upper surface is polished up to the position of the upper surface of the Si₃N₄ layer 43 by using the CMP method. Consequently, the Si layer 57 that has the same shape as that of the Si layer 53 illustrated in FIG. 3EA, FIG. 3EB, and FIG. 3EC is formed. Subsequently, the same processing as that in FIG. 2FA to FIG. 2KC is performed, and the memory cell is formed on the P-layer substrate 11.

The Si layer 57 that has the same shape as that of the Si layer 53 illustrated in FIG. 3EA, FIG. 3EB, and FIG. 3EC can be formed also by using the selective epitaxial crystal growth method as described above.

### Fourth Embodiment

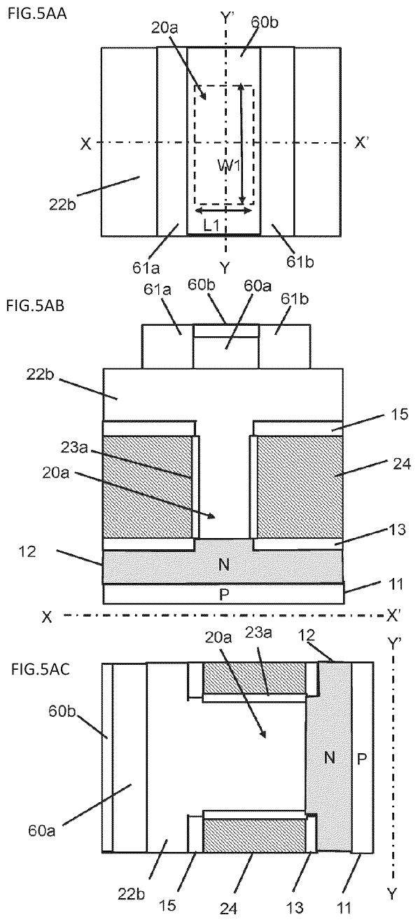

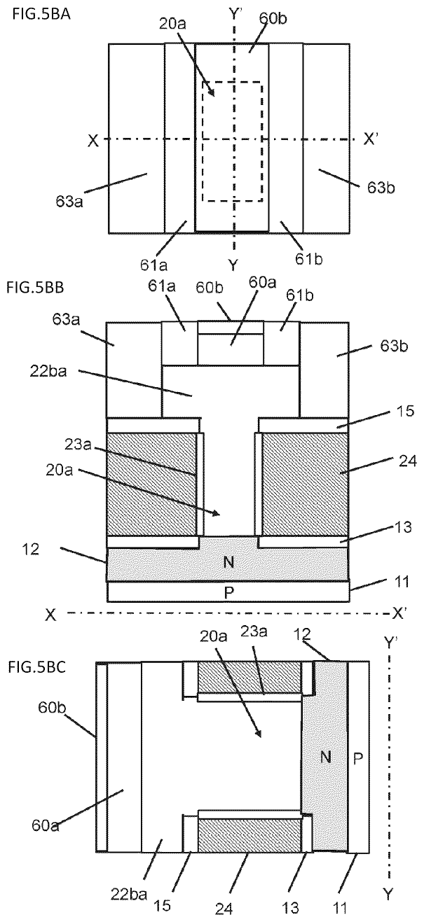

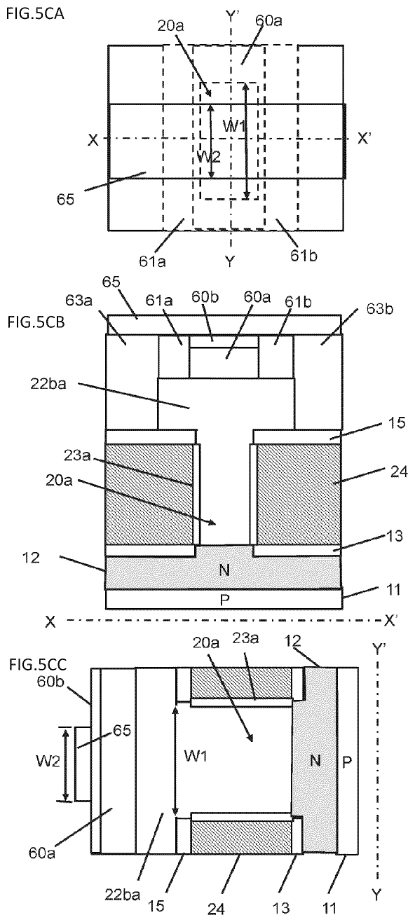

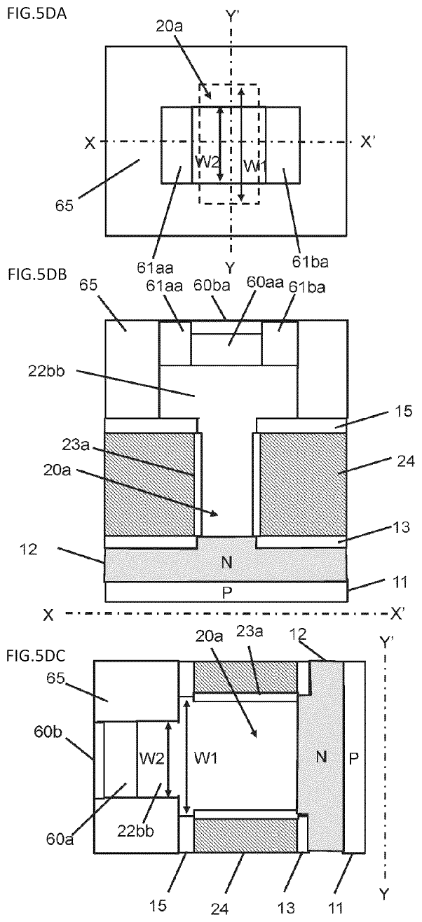

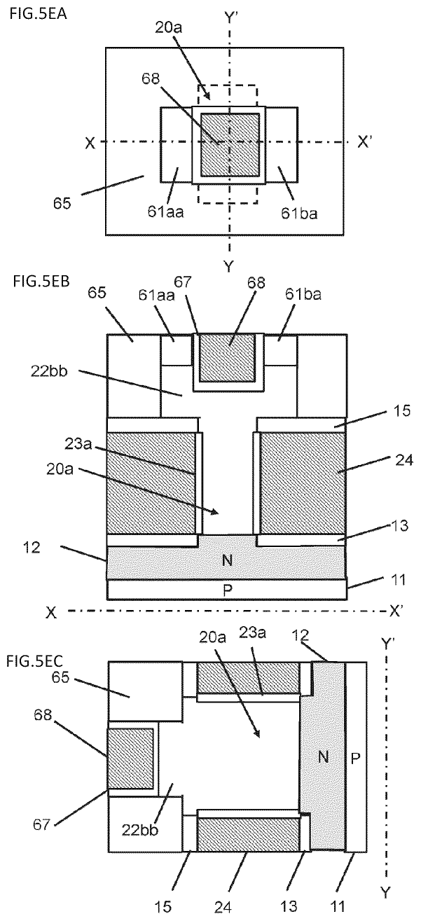

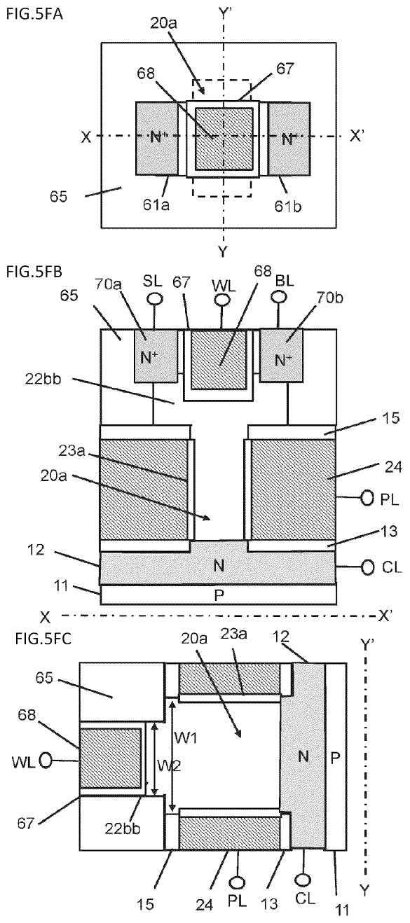

A method of manufacturing a memory cell according to the fourth embodiment will be described with reference to FIG. 5AA to FIG. 5FC. FIG. 5AA, FIG. 5BA, FIG. 5CA, FIG. 5DA, FIG. 5EA, and FIG. 5FA illustrate the memory cell in a plan view. FIG. 5AB, FIG. 5BB, FIG. 5CB, FIG. 5DB, FIG. 5EB, and FIG. 5FB illustrate a vertical section along a line X-X′ in FIG. 5AA, FIG. 5BA, FIG. 5CA, FIG. 5DA, FIG. 5EA, and FIG. 5FA. FIG. 5AC, FIG. 5BC, FIG. 5CC, FIG. 5DC, FIG. 5EC, and FIG. 5FC illustrate a vertical section along a line Y-Y′ in FIG. 5AA, FIG. 5BA, FIG. 5CA, FIG. 5DA, FIG. 5EA, and FIG. 5FA. As for the actual memory device, multiple memory cells are arranged in a two-dimensional array on a substrate. A mechanism for driving the memory cell is the same as that illustrated in FIG. 1A, FIG. 1B, FIG. 1C, and FIG. 1D.

Processing in FIG. 2AA to FIG. 2EC is performed, and as illustrated in FIG. 5AA, FIG. 5AB, and FIG. 5AC, the first Si layer 20a and an Si layer 22b are formed. An Si₃N₄ layer 60a and an SiO₂ layer 60b that have a laminated structure that extends in the direction of the line Y-Y′ are formed on the Si layer, and SiO₂ layers 61a and 61b that have the same width are formed along both sides of the laminated structure. The formation is such that both edges of the Si₃N₄ layer 60a in the direction of the line X-X′ overlap both edges of the first Si layer 20a in a plan view. Both edges of the Si₃N₄ layer 60a may overlap both edges of the first Si layer 20a inside or outside both edges of the first Si layer 20a.

Subsequently, as illustrated in FIG. 5BA, FIG. 5BB, and FIG. 5BC, the Si layer 22b is etched with the SiO₂ layers 60b, 61a, and 61b and the Si₃N₄ layer 60a used as masks, and an Si layer 22ba is formed. Si₃N₄ layers 63a and 63b are formed outside these by using the CVD method and the CMP method.

Subsequently, as illustrated in FIG. 5CA, FIG. 5CB, and FIG. 5CC, a mask material layer 65 that extends in the direction of the line X-X′ and that has a width W2 such that the positions of both edges of the width W2 are inside the positions of both edges of the first Si layer 20a that has a width W1 in a plan view is formed.

Subsequently, as illustrated in FIG. 5DA, FIG. 5DB, and FIG. 5DC, the SiO₂ layers 60b, 61a, 61b, 63a, and 63b, the Si₃N₄ layer 60a, and the Si layer 22ba are etched by using the RIE method with the mask material layer 65 used as a mask, and SiO₂ layers 60ba, 61aa, and 61ba, an Si₃N₄ layer 60aa, and an Si layer 22bb are formed. The SiO₂ layer 65 is formed along the outer periphery thereof by using the CVD method and the CMP method.

Subsequently, polishing is entirely performed by using the CMP method such that the position of an upper surface reaches the position of an upper surface of the Si₃N₄ layer 60aa. Subsequently, the Si₃N₄ layer 60aa and an upper portion of the Si layer 22bb below the Si₃N₄ layer 60aa are etched with the SiO₂ layers 61aa, 61ba, and 65 used as masks, and the Si layer 22bb that has a U-shaped section taken along the line X-X′ and a hole (not illustrated) that is surrounded by the Si layer 22bb are formed As illustrated in FIG. 5EA, FIG. 5EB, and FIG. 5EC, an HfO₂ layer 67 is formed on a side surface of the hole. A TiN-layer 68 that is in contact with an inner side surface of the HfO₂ layer 67 and that fills the hole is formed.

Subsequently, as illustrated in FIG. 5FA, FIG. 5FB, and FIG. 5FC, N⁺ layers 70a and 70b that are in contact with both edges of the Si layer 22bb that has a U-shape are formed. Consequently, a MOS transistor that includes the Si layer 22bb that serves a channel, the N⁺ layers 70a and 70b that serve as a source and a drain, the HfO₂ layer 67 that serves as a gate insulating layer, and the TiN-layer 68 that serves as a gate conductor layer is formed on the first Si layer 20a. The N-layer 12 is connected to the control line CL, the first gate conductor layer 24 is connected to the control line PL, the TiN-layer 68 is connected to the word line WL, the N⁺ layer 70a is connected to the source line SL, and the N⁺ layer 70b is connected to the bit line BL as in FIG. 2MA, FIG. 2MB, and FIG. 2MC.

As illustrated in FIG. 5FC, both edges of a bottom portion of the Si layer 22bb that has the width W2 are inside both edges of the top of the first Si layer 20a that has the width W1 in a vertical section along the line Y-Y′. Consequently, the voltage of the channel of a portion of the Si layer 22bb that is in contact with the first Si layer 20a is controlled by the holes that are stored in the first Si layer 20a with certainty as in the second Si layer 22aa in FIG. 2MA, FIG. 2MB, and FIG. 2MC. As a result, the memory cell that has a large difference between “1” and “0” signals is obtained.

### OTHER EMBODIMENTS

The TiN-layer 24 that is connected to the plate line PL in FIG. 2MA, FIG. 2MB, and FIG. 2MC may be shared with an adjacent memory cell. The TiN-layer 24 may be divided into pieces in the horizontal or perpendicular direction, and these may be connected to respective individual plate lines. The same is true for the other embodiments.

In FIG. 2AA to FIG. 2MC, a P-well structure or a silicon on insulator (SOI) substrate may be used instead of the P-layer substrate 11. The same is true for the other embodiments.

In FIG. 2AA to FIG. 2MC, the concentrations of impurities in the first Si layer 20a and the second Si layer 22aa may differ from each other. The same is true for the other embodiments.

The N-layer 12 and the N⁺ layers 30a and 30b may be formed by using a P⁺ layer the holes of which correspond to the majority carrier, the electrons may correspond to a carrier for writing, and the memory may be operated. The same is true for the other embodiments.

In FIG. 2AA to FIG. 2MC, the shape of the vertical section of the first Si layer 20a is a rectangular shape but may be a trapezoidal shape. The same is true for the other embodiments. A horizontal section of the first Si layer 20a may be a square shape or a rectangular shape. The same is true for the other embodiments.

In FIG. 2MA, FIG. 2MB, and FIG. 2MC, the N-layer 12 is illustrated so as to be connected to the adjacent memory cell but may be present at only the bottom portion of the first Si layer 20a. The connection may be made in a direction in which the word line WL or the bit line BL extends in a plan view. The same is true for the other embodiments.

In the case where the N-layer 12 illustrated in FIG. 2MA, FIG. 2MB, and FIG. 2MC is connected to the adjacent memory cell and is connected to the control line CL, a conductor layer may be provided on the entire surface or a portion of the N-layer 12 along the outer periphery of the first Si layer 20a in a plan view. The same is true for the other embodiments.

In FIG. 5FA, FIG. 5FB, and FIG. 5FC, a lightly doped drain (LDD) region may be provided between the N⁺ layers 70a and 70b and the Si layer 22bb.

In processing illustrated in FIG. 2AA to FIG. 2MC, as for the SiO₂ layers 13, 15, 23a, 23b, 26a, 26b, 35, 36, and 39, the Si₃N₄ layers 14, 25, and 25a, the TiN-layers 24 and 34, and the HfO₂ layer 33, another material layer that includes a single layer or a multilayer may be used provided that the purpose of the processing described above is satisfied. Also according to the other embodiments, another material layer that includes a single layer or a multilayer may be used provided that the material layer to be used satisfies the purpose of processing.

The N⁺ layers 30a and 30b in FIG. 2AA to FIG. 2MC may be in contact with the N-layers 28a and 28b and may be formed by using a selective epitaxial method.

As for the present invention, various embodiments and modifications can be made without departing from the range and spirit of the present invention in a broad sense. The embodiments are described above to describe examples of the present invention and do not limit the range of the present invention. The examples described above and modifications can be freely combined. One obtained by removing some of components according to the embodiments described above as needed is within the range of the technical idea of the present invention.

The use of a semiconductor device that includes a memory element according to the present invention enables a semiconductor device that has high performance and high integrity to be provided.

What is claimed is:

1. A semiconductor device including a memory element, comprising:
a first semiconductor layer that is erected above a substrate in a direction perpendicular to the substrate and that is columnar;
a first impurity region that is connected to a bottom portion of the first semiconductor layer;
a first gate insulating layer that is in contact with a side surface of the first semiconductor layer;
a first gate conductor layer that is in contact with the first gate insulating layer;
a first insulating layer that insulates the first impurity region and the first gate conductor layer from each other;
a second semiconductor layer that includes a bottom portion that is in contact with a top of the first semiconductor layer;
a second insulating layer that is on the first gate conductor layer and that surrounds a vicinity of a boundary between the first semiconductor layer and the second semiconductor layer;
a second gate insulating layer that is in contact with the second semiconductor layer;
a second gate conductor layer that is in contact with the second gate insulating layer; and
a second impurity region and a third impurity region that are along both edges of the second semiconductor layer in a first direction in a plan view,
wherein positions of both edges of the top of the first semiconductor layer in a second direction perpendicular to the first direction are outside positions of both edges of the bottom portion of the second semiconductor layer in a plan view.

2. The semiconductor device according to claim 1,
wherein the first gate conductor layer is connected to a plate line,
wherein the second gate conductor layer is connected to a word line,
wherein the first impurity region is connected to a control line,
wherein the second impurity region is connected to a source line, and
wherein the third impurity region is connected to a bit line.

3. The semiconductor device according to claim 1,
wherein positions of both edges of the second gate conductor layer in the first direction and the second direction substantially match positions of both edges of the second semiconductor layer in a plan view, and
wherein a metal wiring layer is in contact with the second gate conductor layer and extends in the second direction.

4. The semiconductor device according to claim 1,
wherein the first gate conductor layer is divided into multiple gate conductor layers in a plan view, and the divided gate conductor layers are driven by applying a synchronous or asynchronous voltage thereto.

5. The semiconductor device according to claim 1,
wherein the first impurity region is isolated from an adjacent memory cell, and
wherein the third impurity region that has conductivity opposite that of the first impurity region is in contact with a bottom of the first impurity region.

6. The semiconductor device according to claim 1,
wherein the first impurity region extends in a direction in which the word line extends in a plan view, is shared with an adjacent memory cell that is located in the direction in which the word line extends, and is isolated from an adjacent memory cell that is located in a direction perpendicular to the direction in which the word line extends.

7. The semiconductor device according to claim 1,
wherein the first gate conductor layer is divided into multiple gate conductor layers in a plan view, and the divided gate conductor layers are synchronously or asynchronously driven.

8. The semiconductor device according to claim 1,
wherein a voltage that is applied to the first to third impurity regions and the first and second gate conductor layers is controlled, an electric current is caused to flow through the second semiconductor layer between the second impurity region and the third impurity region, and a data writing operation is performed such that a majority carrier in electrons and holes that are generated in the second semiconductor layer due to an impact ionization phenomenon or a gate-induced drain leakage (GIDL) current is mainly stored in the first semiconductor layer by using the electric current, and a data wiping operation is performed such that the majority carrier that is stored in the first semiconductor layer is discharged from the first semiconductor layer.
